(19) United States
(12) Patent Application Publication
(10) Pub. No.: US 2011/0100435 A1
(43) Pub. Date: May 5, 2011

(54) PHOTOVOLTAIC MODULE

(75) Inventors: Satoru Ogasahara, Ichinomiya-City (JP); Toshiyuki Kodera, Yoro-gun (JP)

(73) Assignee: SANYO ELECTRIC CO., LTD., Moriguchi-shi (JP)

(21) Appl. No.: 12/911,121

(22) Filed: Oct. 25, 2010

(30) Foreign Application Priority Data
Oct. 30, 2009 (JP) 2009-251327

(51) Int. Cl. H01L 31/048

(52) U.S. Cl. 136/251

(57) ABSTRACT

To provide a photovoltaic module having a frame arranged on the rear surface of the photovoltaic module, in which the frame has a fixed portion fixed to the photovoltaic module and an end portion standing from the fixed portion relative to the rear surface of the photovoltaic module.

### CROSS-REFERENCE TO RELATED APPLICATIONS

The entire disclosure of Japanese Patent Application No. 2009-251327 filed on Oct. 30, 2009, including specification, claims, drawings, and abstract, is incorporated herein by reference in its entirety.

### BACKGROUND OF THE INVENTION

1. Field of the Invention

The present invention relates to a photovoltaic module.

2. Description of the Related Art

Photovoltaic systems, such as solar power generation systems, or the like, are generally formed as photovoltaic modules comprising a plurality of photovoltaic cells connected in series-parallel and sealed with filler or the like, and an integrally formed structural body, such as a metallic frame, or the like. A photovoltaic system is installed by mounting the photovoltaic module on a support structure placed in an installation position.

For example, there has been disclosed a photovoltaic module having a U-shaped cross sectional frame divided along the periphery of the photovoltaic module, for fixedly holding the photovoltaic module by inserting the periphery of the module into the opening of the U-shaped cross section.

Also known is a photovoltaic module 100 having a photovoltaic module 14 formed thereon being sandwiched between a front side glass 16 and a rear side glass 12, as shown in FIG. 8. Such a photovoltaic module 100 has a bridge structure frame 10, both end portions 10a of which are adhered to the rear side glass 12, and which has a lateral surface portion 10c connecting both of the end portions 10a and a middle part 10b such that the middle part 10b is located apart from the rear side glass 12.

Here, for a photovoltaic module 100 having such a conventional frame 10, in stacking a plurality of photovoltaic modules 100 for transportation, the photovoltaic modules 100 need to be displaced from one another, while being placed one on the other with the rear surfaces thereof facing each other, by an amount corresponding to the width W of the projection of the frame 10, as shown in FIG. 9. This makes the photovoltaic modules 100 bulky, thus causing a problem of increased transport cost.

### SUMMARY OF THE INVENTION

According to one aspect of the present invention, there is provided a photovoltaic module comprising a frame placed on a rear surface of the photovoltaic module, for fixing the photovoltaic module to a support structure when installing the photovoltaic module, wherein the frame has a fixed portion fixed to the photovoltaic module and an end portion standing from the fixed portion relative to the rear surface of the photovoltaic module.

### BRIEF DESCRIPTION OF THE DRAWINGS

FIG. 1 is a cross sectional view of a structure of a photovoltaic module according to an embodiment of the present invention;

FIG. 2 is a plan view showing a structure of a photovoltaic module according to the embodiment of the present invention;

FIG. 3 is a cross sectional view showing another example of a structure of a photovoltaic module according to the embodiment of the present invention;

FIG. 4 is a cross sectional view showing a photovoltaic module mounted according to the embodiment of the present invention;

FIG. 5 is a cross sectional view showing a photovoltaic module mounted according to the embodiment of the present invention;

FIG. 6 is a cross sectional view showing a photovoltaic module in transportation according to the embodiment of the present invention;

FIG. 7 is a cross sectional view showing a photovoltaic module in transportation according to the embodiment of the present invention;

FIG. 8 is a cross sectional view showing a structure of a photovoltaic module according to related art; and

FIG. 9 is a cross sectional view showing a photovoltaic module in transportation when transported according to related art.

### DESCRIPTION OF THE PREFERRED EMBODIMENTS

As shown in the cross sectional view in FIG. 1, a photovoltaic module 200 according to an embodiment of the present invention comprises a front side substrate 20, a photovoltaic cell 22, a rear side substrate 24, and a frame 26.

The front side substrate 20 is a member for supporting the photovoltaic cell 22 on the front surface side thereof. The front side substrate 20 is made using light-transmitting material, such as, for example, glass, plastic, and the like, so as to guide incident light to the photovoltaic cell 22.

The rear side substrate 24 is a member for supporting the photovoltaic cell 22 on the rear surface side thereof. For a photovoltaic module 200 capable of receiving light from both of the front and rear surfaces thereof, the rear side substrate 24 is also made using light-transmitting material, such as, for example, glass, plastic, and the like. Meanwhile, for a photovoltaic module 200 capable of receiving light only from the front surface thereof, the rear side substrate 24 may be made using material which does not pass light, such as metal, cured resin, including epoxy, urethane, thermoplastic resin, or the like.

The photovoltaic cell 22 has a laminated structure including a transparent electrically conductive layer and a photovoltaic layer. As a transparent electrode layer, transparent electrically conductive oxide (TCO) formed by doping tin (Sn), antimony (Sb), fluorine (F), aluminum (Al), or the like to stannous oxide (SnO₂), zinc oxide (ZnO), indium tin oxide (ITO), or the like can be used. The photovoltaic layer is formed on the transparent electrically conductive layer. As a photovoltaic layer, for example, an amorphous silicon photovoltaic layer, a microcrystal silicon photovoltaic layer, and a tandem structure thereof, and a compound semiconductor photovoltaic layer, such as a gallium arsenide base or the like, can be used. In a case of using an amorphous silicon photovoltaic layer or a microcrystal silicon photovoltaic layer, preferably, a PN-type photovoltaic layer including p-type and n-type semiconductor layers laminated, or a PIN-type photovoltaic layer including p-type, i-type and n-type semiconductors laminated may be employed.

The photovoltaic cell 22 may have a structure in which the transparent electrically conductive layer and the photovoltaic layer are divided by a separating groove formed using laser beam or the like such that a plurality of photovoltaic cells are connected in series or in parallel. As a laser beam, e.g., a YAG laser having wavelengths of 1064 nm and 532 nm may be used.

For a photovoltaic module 200 capable of receiving light from both of the front and rear surfaces thereof, the photovoltaic cell 22 may be formed on each of the front side substrate 20 and the rear side substrate 24 so that the photovoltaic cells 22 are connected to each other with the inter layer consisting of the transparent electrically conductive layer, the metal layer, or the like, in-between.

Meanwhile, for a photovoltaic module 200 capable of receiving light from only from the front surface, the photovoltaic cell 22 is formed on the front side substrate 20, on which rear electrodes, resin, and the like are provided, with the rear side substrate 24 further placed thereon. Preferably, the rear electrode has a laminated structure including, e.g., reflective metal and transparent electrically conductive oxide (TCO). As reflective metal, silver (Ag), aluminum (Al), and the like are available. As transparent electrically conductive oxide (TCO), stannous oxide (SnO₂), zinc oxide (ZnO), indium tin oxide (ITO), and the like, are available. As resin, resin material, such as EVA or the like, may be preferably used.

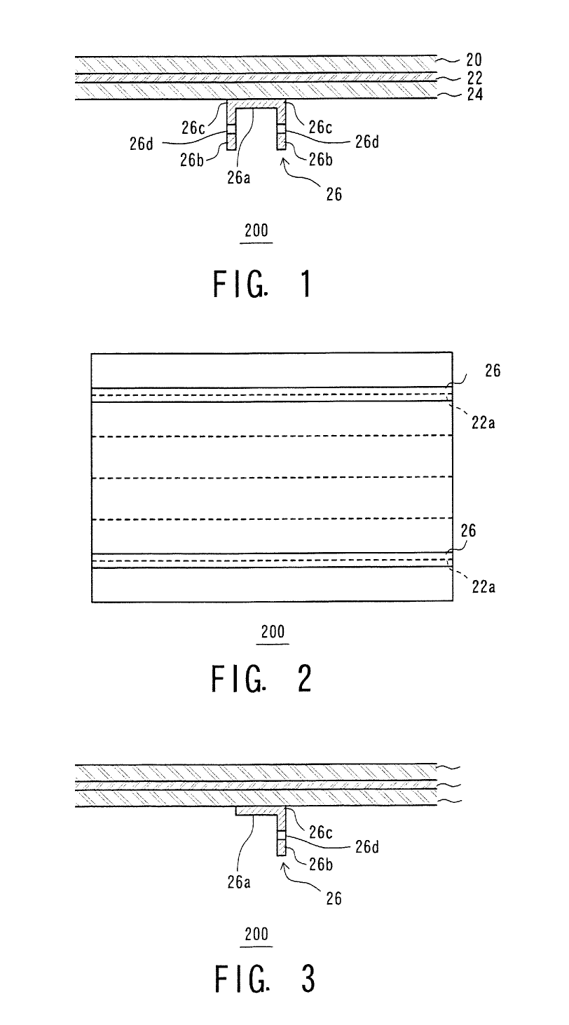

As shown in the plan view of the photovoltaic module 200 viewed from the rear surface side thereof in FIG. 2, the frame 26 is provided on the rear side substrate 24 of the photovoltaic module 200. The frame 26 is fixed to a support structure, using a fixing member, such as a fastening member or the like, when the photovoltaic module 200 is mounted, and used to fix the photovoltaic module 200 to the support structure.

The frame 26 is made using material having mechanical strength sufficient to mount and support the photovoltaic module 200. The frame 26 can be made using, metal, reinforced plastic, and the like. Preferably, the frame 26 is made using, for example, an aluminum member

The frame 26 may have a strip or bar shape having a desired dimension. However, preferably, to be reliably and stably fixed to the support structure, the frame 26 has an extending form like a bar, as shown in FIG. 2.

A position in which to fix the frame 26 is not limited. However, the frame 26 is preferably arranged overlapping the separating groove 22a formed on the photovoltaic cell 22. With the above, the light having passed through the photovoltaic module 200 via the separating groove 22a is reflected by the frame 26 so that the light is introduced again to the photovoltaic cell 22, which can improve photovoltaic efficiency of the photovoltaic module 200. Therefore, preferably, the frame 26 is made using highly light reflecting material or color. For example, preferably, the frame 26 may be made using metal with a high reflective rate, such as aluminum, or the like. In addition, preferably, the frame 26 may be colored white or the like as the color white has a high reflective rate.

As shown in the cross sectional view in FIG. 1, the frame 26 comprises a fixed portion 26a fixed on the rear side substrate 24 of the photovoltaic module 200 and end portions 26b extending from the fixed portion 26a with a bent portion 26c between the end portion 26b and the fixed portion 26a so as to stand from the surface of the rear side substrate 24. The fixed portion 26a is fixed to the rear side substrate 24 of the photovoltaic module 200 by means of adhesive agent or the like.

A fixing member hole 26d is formed on the end portion 26b, for use in fixing the frame 26 to the support structure. Preferably, the fixing member hole 26d is formed penetrating the lateral surface of the end portion 26b. Alternatively, instead of the fixing member hole 26d, an engaging structure to be engaged with an engagement member formed on the support structure may be formed on either the fixed portion 26a or the end portion 26b.

The frame 26 may have a U-shaped cross section having end portions 26b standing on the respective sides of the fixed portion 26a, as shown in FIG. 1, or an L-shaped cross section having the end portion 26b standing on only one side of the fixed portion 26a, as shown in FIG. 3. The U-shaped cross section can enhance mechanical strength when the photovoltaic module 200 is fixed, compared to the L-shaped cross section. Meanwhile, the L-shaped cross section can reduce the weight of the photovoltaic module 200, compared to the U-shaped cross section.

The frame 26 may be formed integral to the rear side substrate 24. With this structure, it is unnecessary to fix the frame 26 to the rear side substrate 24, using adhesive agent, which can enhance mechanical strength when the photovoltaic module 200 is fixed.

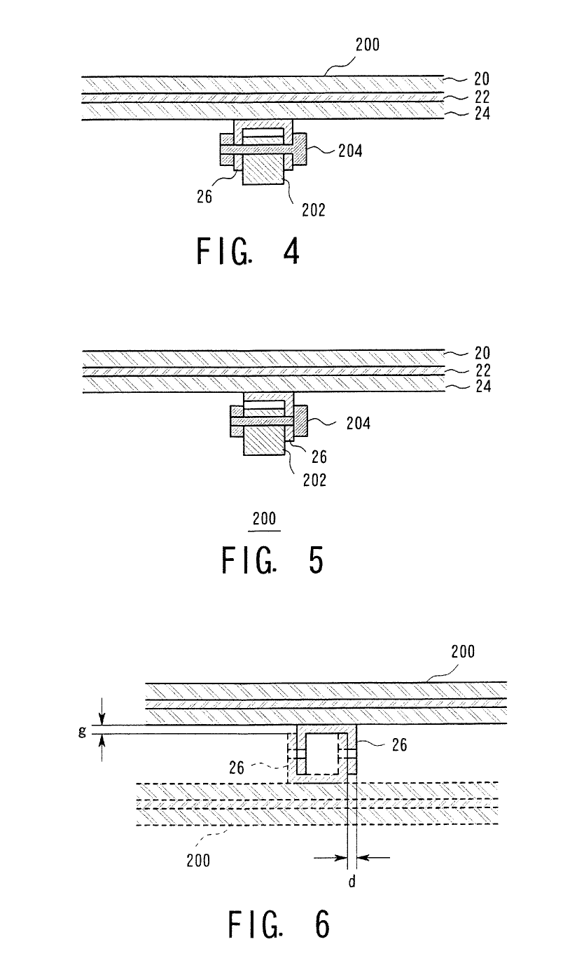

In installation, the photovoltaic module 200 can be fixed to the support structure 202 placed in an installation position, using the fixing member 204 and the fixing member hole 26d formed on the frame 26, as shown in FIGS. 4 and 5.

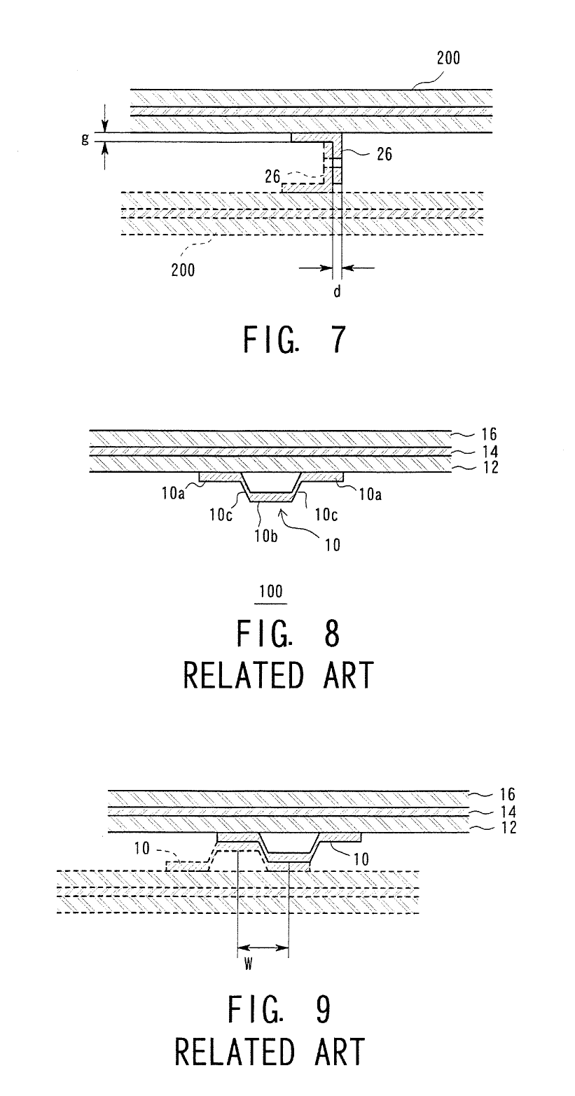

For transportation, the photovoltaic module 200 can be transported, being stacked with the rear surfaces thereof facing each other, as shown in FIGS. 6 and 7. In stacking, photovoltaic module 200 can be displaced by only an amount corresponding to the thickness d of the end portion 26b of the frame 26, as shown in FIGS. 6 and 7. This can reduce the bulkiness of the photovoltaic module 200 in transportation, compared to a conventional manner of transportation in which the photovoltaic modules 200 need to be stacked with displacement by an amount corresponding to the width W of the entire frame.

In stacking the photovoltaic modules 200, a space g is caused between the photovoltaic modules 200 due to the thickness d of the frame 26, as shown in FIGS. 6 and 7. The space g can prevent the photovoltaic modules 200 from contacting each other during transportation. With the above, it is possible to reduce damage on the photovoltaic module 200 during transportation.

In particular, for a U-shaped cross sectional frame 26, the amount of sideways displacement, if it occurs, of the stacked photovoltaic modules 200 is reduced by the end portion 26b of the frame 26. This can prevent the frame 26 from contacting the rear side substrate 24 of an adjacent stacked photovoltaic module 200 due to the photovoltaic modules 20 being displaced during transportation, and thus reduce damage on the photovoltaic module 200 during transportation.

Note that as shown in FIGS. 1 and 3, the frame 26 may be shaped such that the end portion 26b stands substantially vertically from the rear side substrate 24 or the end portion 26b stands from the rear side substrate 24 with an angle smaller than 90°. The latter shape has an advantage of facilitating insertion of the frame 26 into the support structure 202 when mounting the photovoltaic module 200. Meanwhile, the former shape has an advantage that the photovoltaic modules 200 need to be displaced by only an amount corresponding to the thickness d of the end portion 26d when stacking the photovoltaic modules 200.

Preferably, the fixed portion 26a, the end portion 26b, and the bent portion 26c are formed integrally. However, separate members maybe assembled, rather than being integral, as long as sufficient mechanical strength is obtained.

What is claimed is:

1. A photovoltaic module, comprising:
a photovoltaic cell,
a rear side substrate, for supporting the photovoltaic cell on a rear surface side,
a frame placed on a rear surface of the photovoltaic module, for fixing the photovoltaic module to a support structure when installing the photovoltaic module, and
the frame having a fixed portion fixed to the photovoltaic module and an end portion standing from the fixed portion relative to the rear surface of the photovoltaic module.

2. The photovoltaic module according to claim 1, wherein both ends portions of the frame stand from the fixed portion relative to the rear surface of the photovoltaic module.

3. The photovoltaic module according to claim 1, wherein the end portion has a fixing hole formed thereon for fixing the photovoltaic module to the support structure.

4. The photovoltaic module according to claim 2, wherein the end portion has a fixing hole formed thereon for fixing the photovoltaic module to the support structure.

5. The photovoltaic module according to claim 1, wherein the frame is arranged along a separating groove of a photovoltaic cell, the separating groove being formed on the photovoltaic module.

6. The photovoltaic module according to claim 2, wherein the frame is arranged along a separating groove of a photovoltaic cell, the separating groove being formed on the photovoltaic module.

7. The photovoltaic module according to claim 3, wherein the frame is arranged along a separating groove of a photovoltaic cell, the separating groove being formed on the photovoltaic module.

8. The photovoltaic module according to claim 1, wherein the end portion stands substantially vertically relative to the rear surface of the photovoltaic module.

9. The photovoltaic module according to claim 2, wherein the end portion stands substantially vertically relative to the rear surface of the photovoltaic module.

10. The photovoltaic module according to claim 3, wherein the end portion stands substantially vertically relative to the rear surface of the photovoltaic module.

11. The photovoltaic module according to claim 4, wherein the end portion stands substantially vertically relative to the rear surface of the photovoltaic module.
